(19) United States
(12) Patent Application Publication
(10) Pub. No.: US 2019/0036078 A1
(43) Pub. Date: Jan. 31, 2019

(54) ORGANIC EL DISPLAY DEVICE

(71) Applicant: Futaba Corporation, Mobara-shi (JP)

(72) Inventors: Takahiro NIIYAMA, Mobara-shi (JP); Shinji IDE, Mobara-shi (JP); Mitsufumi KODAMA, Mobara-shi (JP); Shingo KAMINAGA, Kitaibaraki-shi (JP)

(21) Appl. No.: 16/044,041

(22) Filed: Jul. 24, 2018

(30) Foreign Application Priority Data
Jul. 27, 2017 (JP) 2017-145604

(51) Int. Cl. H01L 51/52; H01L 27/32

(52) U.S. Cl. CPC H01L 51/5259; H01L 2251/5323; H01L 51/5246; H01L 27/3281

(57) ABSTRACT

An organic EL display device includes a first substrate, a frame-shaped sealing layer disposed along an edge of the first substrate, a second substrate, an organic EL element portion disposed in a sealed space surrounded with the first substrate, the sealing layer, and the second substrate, and a filler that fills the sealed space. The filler has a first filler that includes a powdered drying agent, and is in contact with the sealing layer on an inside of the sealing layer, and a second filler that is in contact with the first filler on an inside of the first filler. At least an area overlapping the organic EL element portion is filled with the second filler.

### CROSS-REFERENCE TO RELATED APPLICATIONS

This application is based upon and claims the benefit of priority from Japanese Patent Application No. 2017-145604, filed on 27 Jul. 2017, the entire contents of which are incorporated herein by reference.

### TECHNICAL FIELD

The present disclosure relates to an organic EL display device.

### BACKGROUND

In recent years, as a display device, an organic EL display device which uses an organic electro-luminescence (EL) material as a light-emitting substance is in the spotlight. An organic EL element which is configured by interposing the organic EL material between a pair of electrodes is likely to be influenced by moisture, and for example, deterioration such as oxidation or peeling of the electrode may be generated due to sticking of water. Therefore, a countermeasure against water permeating an area in which the organic EL element is disposed is provided with the organic EL display device.

For example, Japanese Unexamined Patent Publication No. 2012-038659 (PTL 1) discloses an organic EL display device that adopts a so-called hollow sealing structure. In PTL 1, a water catching agent (drying agent) is disposed in a space (sealed space) which is sealed by an element substrate and a sealing substrate. Specifically, the water catching agent is disposed in a depression which is formed in the sealing substrate. Japanese Unexamined Patent Publication No. 2014-201574 (PTL 2) discloses an organic EL element having a so-called filling and sealing structure. In PTL 2, the sealed space described above is filled with a filler into which a drying agent is dispersed.

### SUMMARY

In the organic EL display device having the hollow sealing structure disclosed in PTL 1, the concave portion is formed in the sealing substrate, in order to provide the sealed space. Thereby, there is a concern that mechanical strength of the organic EL display device is not sufficient. Since there is a need to form the depression, a thickness of the sealing substrate becomes large, thereby, there is a problem that a hindrance to reduction in thickness of the organic EL display device is generated. In a case where the hollow sealing structure is adopted in this manner, it is not easy to realize the organic EL display device having flexibility by reducing the thickness.

On the contrary, in the organic EL display device having the filling and sealing structure disclosed in PTL 2, there is no need to form the depression in the sealing substrate, thereby, it is possible to realize the organic EL display device having flexibility by reducing the thickness. In such a filling and sealing structure, it is studied to use a filler including a powdered drying agent of which ability to absorb moisture is high.

However, in a case where the filler including the powdered drying agent is used, the powdered drying agent is ununiformly dispersed or the powdered drying agent is aggregated, thereby, there are concerns that the powdered drying agent strikes an organic EL element portion, and the organic EL element portion is damaged. For example, the sealing substrate or the element substrate is deformed, thereby, the substrates approach to each other, and there are concerns that the powdered drying agent strikes the organic EL element portion, and the organic EL element portion is damaged. If the organic EL element portion is damaged in this manner, a cathode and an anode of the organic EL element portion are in contact with each other, thereby, there are concerns that a dielectric breakdown is caused, a leakage occurs, and reliability of an organic EL display portion is lowered.

The present disclosure will describe an organic EL display device that is capable of securing water catching performance, and preventing lowering in reliability of an organic EL element portion.

According to an aspect of the present disclosure, there is provided an organic EL display device including a first substrate that has a first main surface, a frame-shaped sealing layer that is in contact with the first main surface, and is disposed along an edge of the first substrate, a second substrate that is in contact with the sealing layer, and has a second main surface facing the first main surface, an organic EL element portion that is disposed in a sealed space which is sealed by being surrounded with the first substrate, the sealing layer, and the second substrate on the second main surface, and a filler with which the sealed space is filled. The filler has a first filler that includes a powdered drying agent, and is in contact with the sealing layer on an inside of the sealing layer in a direction intersecting with a layer-stacked direction of the first substrate and the second substrate, and a second filler that is in contact with the first filler on an inside of the first filler in the direction intersecting with the layer-stacked direction, and with which at least an area overlapping the organic EL element portion in the layer-stacked direction is filled.

In the organic EL display device, the first filler that is in contact with the sealing layer on the inside of the sealing layer is disposed in the direction intersecting with the layer-stacked direction, and the first filler includes the powdered drying agent. Thereby, it is possible to dispose the powdered drying agent of which water catching performance is high on the inside of the sealing layer. Therefore, it is possible to suitably absorb moisture which is permeated from an outside, and a concern that the moisture reaches the organic EL element portion is reduced. As a result, an influence due to the moisture on the organic EL element portion is prevented, deterioration of the organic EL element portion is prevented, and lowering in reliability of the organic EL element portion is prevented.

A concentration of the powdered drying agent in the first filler may be higher than a concentration of the powdered drying agent in the second filler. In the organic EL display device, the concentration of the powdered drying agent is higher in the first filler which is disposed on the outside than that in the second filler which is disposed on the inside, in the direction intersecting with the layer-stacked direction. In other words, the concentration of the powdered drying agent in the second filler which is disposed on the inside is lower than the concentration of the powdered drying agent in the first filler which is disposed on the outside. In this manner, the concentration of the powdered drying agent in the second filler with which the area overlapping the organic EL element portion in the layer-stacked direction is filled is made small, thereby, a concern that the powdered drying agent strikes the organic EL element portion is prevented. Thereby, since a concern that the organic EL element portion is damaged is prevented, occurrence of a dielectric breakdown, and occurrence of a leakage are prevented in the organic EL element portion. As a result, it is possible to prevent the lowering in reliability of the organic EL element portion. The second filler may include the powdered drying agent, and may not include the powdered drying agent. In a case where the second filler does not include the powdered drying agent, the concentration of the powdered drying agent in the second filler becomes 0 wt %.

The first filler may be disposed in a frame shape surrounding the organic EL element portion, when viewed from the layer-stacked direction. Thereby, since the first filler including the powdered drying agent surrounds the organic EL element portion, and is disposed around a whole circumference thereof, it is possible to reliably catch the water by the drying agent of the first filler, before the moisture reaches the organic EL element portion. Therefore, the influence due to the moisture on the organic EL element portion is prevented, and the deterioration of the organic EL element portion is prevented, thereby, it is possible to further prevent the lowering in reliability.

The first filler may have a first drying agent which is the drying agent. The second filler may have a second drying agent of a kind which is different from the first drying agent. In this manner, in the first drying agent and the second drying agent, it is possible to use the drying agents of kinds which are different from each other. For example, the drying agents of which ingredients are different from each other are referred to as drying agents of kinds which are different from each other.

The first filler may have a curable resin, and an inorganic oxide drying agent as the drying agent. A concentration of the inorganic oxide drying agent in the first filler may be 30 weight (wt) % or more and 55 wt % or less. Thereby, it possible to suitably catch the water by the inorganic oxide drying agent which is included in the first filler, and it is possible to further prevent the moisture that reaches the organic EL element portion which is disposed on the inside in comparison with the first filler, in the direction intersecting with the layer-stacked direction.

The second filler may have a curable resin, and an inorganic oxide drying agent. A concentration of the inorganic oxide drying agent in the second filler may be 5 wt % or more and 20 wt % or less. Thereby, an amount of the inorganic oxide drying agent which is included in the second filler is kept to be low, thereby, the amount of the powdered drying agent that is present in the area overlapping the organic EL element portion in the layer-stacked direction is kept to be low, and a concern that the powdered drying agent strikes the organic EL element portion is prevented. Since the inorganic oxide drying agent is present in the area overlapping the organic EL element portion, even if the moisture is permeated, it is possible to catch the water by the inorganic oxide drying agent.

The second filler may include an organic metal as a drying agent.

Each of the first substrate, the second substrate, and the second filler may be configured to have a light-transmitting property. In this case, it is possible to make the organic EL display device be a see-through type display device. In addition, a double-sided light emission of the organic EL display device becomes possible.

The first substrate and the second substrate may be film-shaped substrates or glass substrates. Thereby, it is possible to realize the organic EL display device which has suitable flexibility, and improves softness.

According to the present disclosure, it is possible to provide the organic EL display device that is capable of securing water catching performance, and preventing lowering in reliability of the organic EL element portion.

### BRIEF DESCRIPTION OF THE DRAWINGS

FIG. 1 is a schematic plan view of an organic EL display device according to an embodiment.

FIG. 2 is a schematic sectional view taken along A-A line in FIG. 1.

FIG. 3 is a schematic sectional view taken along B-B line in FIG. 2.

FIG. 4A is a schematic sectional view of an organic EL element portion.

FIG. 4B is a schematic sectional view illustrating the organic EL element portion in a case where aggregation of a powdered drying agent occurs.

FIG. 4C is a schematic sectional view illustrating the organic EL element portion in a case where a portion in which a concentration of the powdered drying agent is high occurs.

FIG. 4D is a schematic sectional view illustrating the organic EL element portion in a case where deformation occurs in a first substrate and a second substrate.

### DETAILED DESCRIPTION

Hereinafter, appropriate embodiments of the present disclosure will be described in detail with reference to accompanying drawings. In the following description, the same marks are used for the same components or components having the same functions, and the repeated description thereof will be omitted.

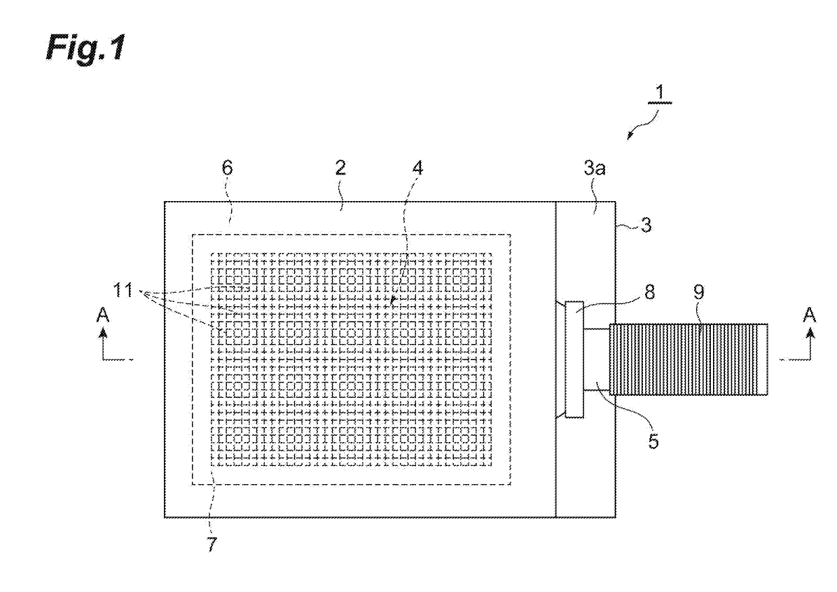

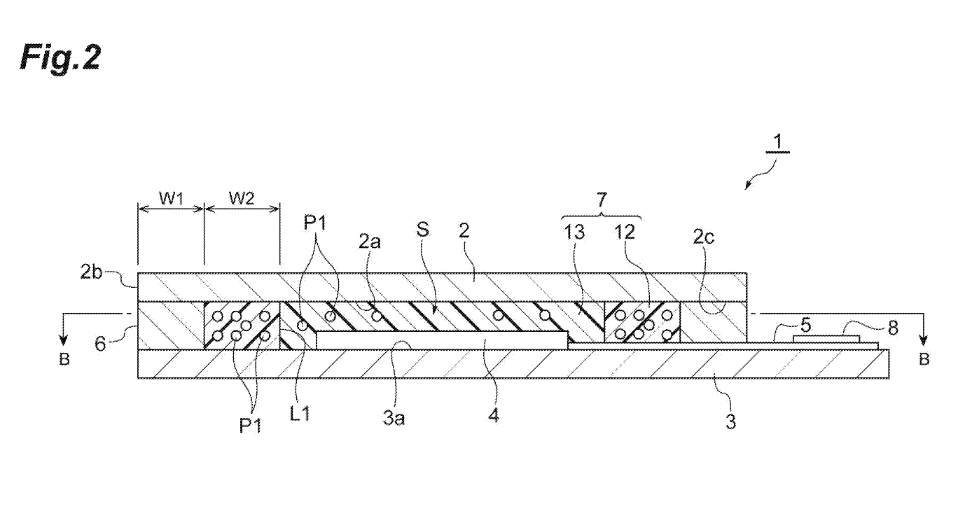

First, a configuration of an organic EL display device according to an embodiment will be described with reference to FIG. 1. FIG. 1 is a schematic plan view of the organic EL display device according to the present embodiment, and FIG. 2 is a schematic sectional view taken along A-A line in FIG. 1.

An organic EL display device 1 according to the present embodiment illustrated in FIG. 1 and FIG. 2 is a passive matrix type display device, and is a see-through type display device. Therefore, in the organic EL display device 1, a double-sided light emission becomes possible. The organic EL display device 1 includes a first substrate 2 and a second substrate 3 which are stacked, an organic EL element portion 4, a wiring portion 5, a sealing layer 6, a filler 7, an integrated circuit 8, a flexible printed circuit board (FPC) 9. Hereinafter, a direction in which the first substrate 2 and the second substrate 3 are stacked on each other will be simply described as a “layer-stacked direction”.

The first substrate 2 is a substrate that functions as a sealing substrate, and is disposed to face the second substrate 3. For example, the first substrate 2 is a glass substrate or a substrate (for example, a plastic substrate or the like) having flexibility, and has a light-transmitting property. In the first substrate 2, a main surface 2a (first main surface) facing the second substrate 3 has a substantially rectangular shape.

For example, a thickness of the first substrate 2 may be 200 μm or less, and may be 100 μm or less, from the viewpoint of softness. The thickness of the first substrate 2 may be 5 μm or more, and may be 10 μm or more, from the viewpoint of securing strength and being easy to handle.

A material of the glass substrate may be the same as that of the second substrate 3, and for example, non-alkali glass, soda-lime glass, or the like may be used. As a first substrate 2, it is possible to use a film-shaped substrate. For example, as a material of the film-shaped substrate, a resin such as polyethylene terephthalate (PET), polyethylene naphthalate (PEN), or polyimide may be used. For example, the thickness of the film-shaped substrate may be 200 μm. If the first substrate 2 and the second substrate 3 are the film-shaped substrates, it is possible to realize the organic EL display device 1 which has suitable flexibility, and improves softness.

In the main surface 2a, an edge area 2c on an edge 2b side is an area in which the sealing layer 6 is disposed. The edge 2b forms a surface along the layer-stacked direction. The edge area 2c has a tetragonal frame shape (frame shape) when viewed from the layer-stacked direction, and a width W1 of the edge area 2c may be, for example, approximately 1 mm to 2 mm. The width W1 of the edge area 2c may be a width which is the same as that, or may be a width which is different from that, on each side of the corresponding tetragon.

The second substrate 3 is an element substrate in which the organic EL element portion 4 and the wiring portion 5 are disposed. In the same manner as the first substrate 2, for example, the second substrate 3 is a glass substrate or a substrate (for example, a plastic substrate or the like) having flexibility, and has the light-transmitting property. A main surface 3a (second main surface) of the second substrate 3 has a substantially rectangular shape, in the same manner as the main surface 2a. A short side of the main surface 3a is substantially the same as the short side of the main surface 2a, and a long side of the main surface 3a is longer than the long side of the main surface 2a. Therefore, in a case where the short sides of the main surfaces 2a and 3a are aligned with each other, a portion of the main surface 3a is exposed from the first substrate 2. For example, a distance between the main surfaces 2a and 3a in the layer-stacked direction may be 10 μm to 30 μm. In the present embodiment, “substantially the same” is not only a concept illustrating to be entirely the same, but also a concept including some errors (for example, approximately several % at most).

For example, the thickness of the second substrate 3 may be substantially the same as the thickness of the first substrate 2. The thickness of the second substrate 3 may be different from the thickness of the first substrate 2. For example, the material of the second substrate 3 may be the same as the material of the first substrate 2.

The organic EL element portion 4 is a portion to which an electric current is supplied, thereby, which generates light, and is disposed on the main surface 3a of the second substrate 3. The organic EL element portion 4 is disposed in an area which is surrounded by the edge area 2c when viewed from the layer-stacked direction, in a sealed space S which is sealed by being surrounded with the first substrate 2, the second substrate 3, and the sealing layer 6. In the organic EL element portion 4, a plurality of organic EL elements 11 which are arranged in a matrix shape, and a cathode separation layer (not illustrated) having a reverse taper shape in cross section are disposed.

For example, each organic EL element 11 is a light-emitting element that has an anode, a cathode, and an organic light-emitting layer which is interposed between the anode and the cathode. For example, the anode is formed on the main surface 3a of the second substrate 3, and the organic light-emitting layer and the cathode are formed in sequence on the anode. As a material which forms the anode, for example, a material such as indium tin oxide (ITO) or indium zinc oxide (IZO) having the light-transmitting property may be used. The organic light-emitting layer may have an electron injection layer, an electron transport layer, a hole transport layer, a hole injection layer, and the like, in addition to the light-emitting layer including a light-emitting material.

The light-emitting material may be a low molecular organic compound, or may be a high molecular organic compound. As a light-emitting material, a fluorescent material may be used, or a phosphorescent material may be used. As a material (conductive material) of a conductive layer which forms the cathode, for example, aluminum, silver, an alkaline earth metal (such as magnesium or calcium), a material such as indium zinc oxide (IZO) or indium tin oxide (ITO) having the light-transmitting property, or the like may be used. In a case where the light is emitted on the first substrate 2 side, the cathode is set to have the thickness having the light-transmitting property.

The wiring portion 5 includes a portion in which a plurality of guidance wirings are disposed. The wiring portion 5 includes the plurality of wirings for connecting the organic EL element portion 4 and the integrated circuit 8. The wiring portion 5 includes the wiring for connecting the integrated circuit 8 and the FPC 9. The wiring portion 5 may be formed in the anode or the cathode of the organic EL element 11 at the same time. The guidance wiring which is included in the wiring portion 5 is formed from single metal layer or a stacked metal layer. For example, a barrier film such as a silicon oxide film or a silicon nitride film may be disposed on a surface of the guidance wiring.

The sealing layer 6 functions as a bonding agent for bonding the first substrate 2 and the second substrate 3, and functions as a side wall for forming the sealed space S. The sealing layer 6 is disposed along the edge area 2c in the main surface 2a of the first substrate 2, and is in contact with the edge area 2c and the main surface 3a of the second substrate 3. Therefore, the width W1 of the sealing layer 6 is stably formed in accordance with the edge area 2c. The sealing layer 6 is also in contact with a portion of the guidance wiring which forms the wiring portion 5.

The sealing layer 6 has a tetragonal frame shape (frame shape) along the shape of the edge area 2c, when viewed from the layer-stacked direction. For example, the sealing layer 6 includes an ultraviolet ray curable resin having an adhesive property. The sealing layer 6 may include a spacer such as silica particles, or the like.

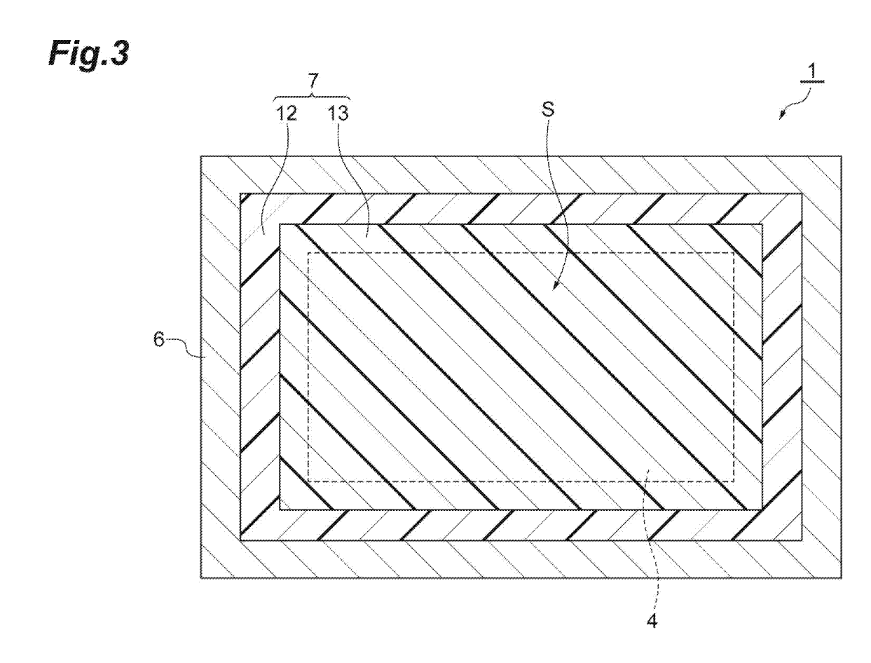

The filler 7 is accommodated in the sealed space S, and a space in the sealed space S is filled with the filler 7. A whole of the sealed space S is filled with the filler 7. As illustrated in FIG. 2 and FIG. 3, the filler 7 has a first filler 12 and a second filler 13.

The first filler 12 has a tetragonal frame shape along the sealing layer 6, when viewed from the layer-stacked direction, on an inside of the sealing layer 6 in a direction intersecting with the layer-stacked direction. The first filler 12 is in contact with the sealing layer 6 in the direction intersecting with the layer-stacked direction. An area not overlapping the organic EL element portion 4, when viewed from the layer-stacked direction, is filled with the first filler 12. The first filler 12 is continuously disposed around a whole circumference of the organic EL element portion 4 by surrounding the organic EL element portion 4, on an outside of the organic EL element portion 4, when viewed from the layer-stacked direction. A portion of the first filler 12 may be disposed at a position overlapping the organic EL element portion 4, when viewed from the layer-stacked direction. The first filler 12 may be partially formed on the outside of the organic EL element portion 4. For example, the first filler 12 may be disposed only in a portion which is equivalent to the outside of a corner portion of the organic EL element portion 4 of a rectangular shape.

In the first filler 12, for example, a liquid state material or a gel state material may be used. As a base material of the first filler 12, for example, various curable resins may be used, from the viewpoint of viscosity adjusting easiness. The first filler 12 includes a powdered drying agent P1 (first drying agent). As a powdered drying agent P1, for example, a drying agent including an inorganic oxide may be used, and as an inorganic oxide, for example, an oxide of an alkaline earth metal may be used. As an oxide of the alkaline earth metal, for example, a magnesium oxide (MgO), a calcium oxide (CaO), a strontium oxide (SrO), a barium oxide (BaO), and the like may be used. The oxide of the alkaline earth metal may be the magnesium oxide and/or the calcium oxide.

The second filler 13 has a tetragonal shape, when viewed from the layer-stacked direction, on the inside of the first filler 12 in the direction intersecting with the layer-stacked direction. The second filler 13 is in contact with the first filler 12 in the direction intersecting with the layer-stacked direction. At least an area overlapping the organic EL element portion 4 in the layer-stacked direction is filled with the second filler 13. The second filler 13 is also disposed on the outside of the area overlapping the organic EL element portion 4. The area of the tetragonal shape on the inside of the tetragonal frame-shaped first filler 12 is filled with the second filler 13. The second filler 13 may be disposed only in the area overlapping the organic EL element portion 4, when viewed from the layer-stacked direction. In the present embodiment, a boundary L1 between the first filler 12 and the second filler 13 is present on the outside of the organic EL element portion 4, when viewed from the layer-stacked direction.

In the second filler 13, for example, a liquid state material or a gel state material having the light-transmitting property is used. A visible ray transmittance of the second filler 13 may be 80% or more. As a base material of the second filler 13, for example, various curable resins may be used, from the viewpoint of viscosity adjusting easiness. For example, the second filler 13 includes the powdered drying agent P1. A concentration C2 [wt %] of the powdered drying agent P1 which is included in the second filler 13 may be lower than a concentration C1 [wt %] of the powdered drying agent P1 which is included in the first filler 12.

The second filler 13 may include the drying agent (second drying agent) of a kind that is different from the drying agent (first drying agent) which is included in the first filler 12. The second filler 13 may include the drying agent having the light-transmitting property, as a second drying agent. Thereby, it is possible to restrain the emission of the light to the first substrate 2 side from being blocked while to favorably prevent water from permeating the organic EL element portion 4 by the drying agent. From the viewpoint of water catching performance, visible ray penetrability, and viscosity adjusting easiness, a liquid state drying agent including a metal alkoxide as a water catching ingredient may be used.

The second filler 13 may include an organic metal as a drying agent. As an organic metal, for example, aluminum, titanium, magnesium, or the like may be used. Since the drying agent of the organic metal is fast in water catching speed, it is possible to efficiently catch the water. For example, the drying agent of the organic metal can efficiently remove moisture which is adsorbed or occluded in the organic EL element portion 4. For example, the drying agent of the organic metal can efficiently remove the moisture which is adsorbed or occluded in the first substrate 2.

Here, the concentration C1 of the powdered drying agent P1 in the first filler 12 becomes higher than the concentration C2 of the powdered drying agent P1 in the second filler 13 (C1>C2). For example, the concentration C1 of the powdered drying agent P1 in the first filler 12 may be 30 wt % or more and 55 wt % or less. If the concentration C1 of the inorganic oxide drying agent in the first filler 12 is 30 wt % or more and 55 wt % or less, it is possible to suitably catch the water by the inorganic oxide drying agent, and it is possible to suitably prevent the moisture from reaching the organic EL element portion 4 which is disposed on the inside in comparison with the first filler 12, in the direction intersecting with the layer-stacked direction.

For example, the concentration C2 of the powdered drying agent P1 in the second filler 13 may be 5 wt % or more and 20 wt % or less. In this manner, the concentration C2 of the powdered drying agent P1 which is included in the second filler 13 is kept low, thereby, an amount of the powdered drying agent P1 which is present in the area overlapping the organic EL element portion 4 in the layer-stacked direction is reduced, and a concern that the powdered drying agent P1 strikes the organic EL element portion 4 is prevented. The inorganic oxide drying agent is present in the area overlapping the organic EL element portion 4, thereby, even if the moisture is permeated, the water is caught by the inorganic oxide drying agent. Thereby, lowering in reliability of the organic EL element portion 4 is prevented.

The second filler 13 may not include the powdered drying agent P1 (C1=0 wt %). The concentrations C1 and C2 of the powdered drying agent P1 may be values which is calculated by calculation, or may be measured values. For example, before beginning of use, the concentration C1 of the powdered drying agent P1 in the first filler 12 becomes higher than the concentration C2 of the powdered drying agent P1 in the second filler 13 (C1>C2).

For example, an average particle diameter of the powdered drying agent P1 can be 0.1 μm or more and 2.0 μm or less.

The integrated circuit 8 is a drive circuit that controls light emission and non-light emission of each organic EL element portion 4. The integrated circuit 8 is mounted in the area which is exposed from the first substrate 2 on the main surface 3a of the second substrate 3, and is connected to the wiring portion 5. For example, the integrated circuit 8 is an IC chip or the like. The number of the integrated circuits 8 which is mounted on the main surface 3a may be one, or may be plural.

The FPC 9 is connected to the wiring portion 5, and is a wiring for connecting the organic EL display device 1 and an external device. For example, the FPC 9 is formed using a plastic substrate having flexibility. For example, the external device which is connected to the FPC 9 is a power source, an electrical current control circuit, or the like.

Next, a method for manufacturing the organic EL display device 1 will be described. For example, the method for manufacturing the organic EL display device 1 includes a filling method with the filler 7 using a one drop filling (ODF) method. In the description of the filling method, the organic EL element portion 4 and the wiring portion 5 will be omitted.

First, the first substrate 2 is prepared, and the sealing layer 6 is disposed on the main surface 2a of the first substrate 2. The sealing layer 6 is disposed along an outer circumference of the main surface 2a of the first substrate 2, and is disposed to form a rectangular shape when viewed from the layer-stacked direction.

Next, the first filler 12 is applied to the area on the inside of the sealing layer 6 with respect to the main surface 2a of the first substrate 2. The first filler 12 is disposed to form a tetragonal frame shape.

Next, the second filler 13 is dropped into the area on the inside of the first filler 12, on the main surface 2a of the first substrate 2. A dropping amount of the second filler 13 is equivalent to a volume of the area on the inside of the first filler 12, in the sealed space S. A spot into which the second filler 13 is dropped may be one spot, or may be a plurality of spots.

Next, the first substrate 2 is sealed by overlapping the second substrate 3 thereto, in a low pressure state or a vacuum state. At that time, a pressure is applied to each of the first substrate 2 and the second substrate 3, and an interval between the first substrate 2 and the second substrate 3 is reduced in the layer-stacked direction. At that time, the second filler 13 in the sealed space S spreads toward the first filler 12 side, while the interval between the second substrate 3 and the second filler 13 is filled with the second filler 13 in the sealed space S. Therefore, the second filler 13 spreads up to being in contact with the first filler 12. After the second substrate 3 is stuck to the first substrate 2, an adhesive is irradiated with an ultraviolet ray in a normal pressure state, and the adhesive is heated, thereby, the sealing layer 6 is formed. The method for manufacturing the organic EL display device 1 is not limited to the manufacturing method described above, and other manufacturing methods may be used.

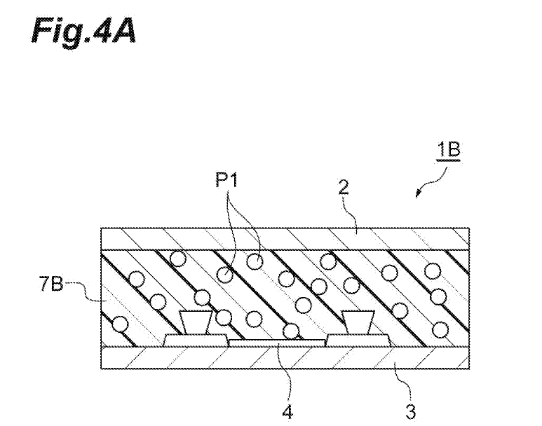

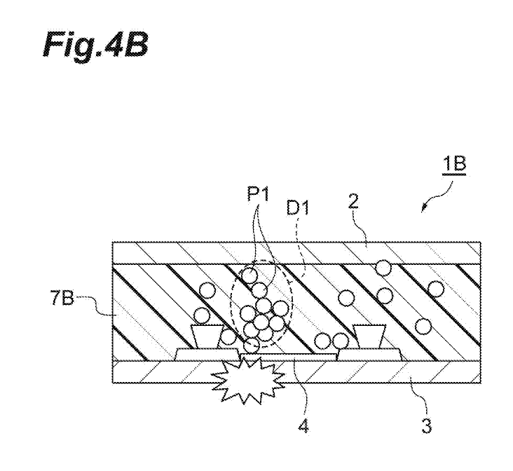

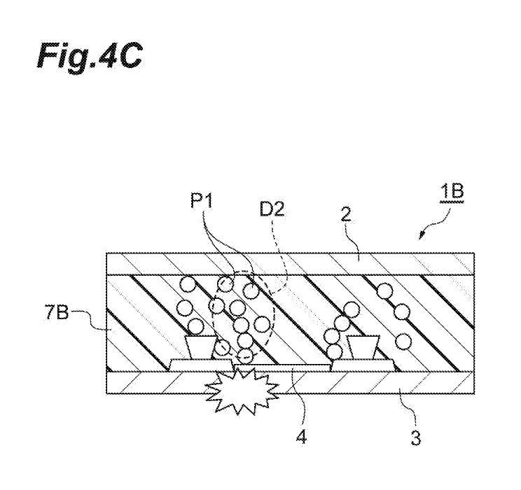

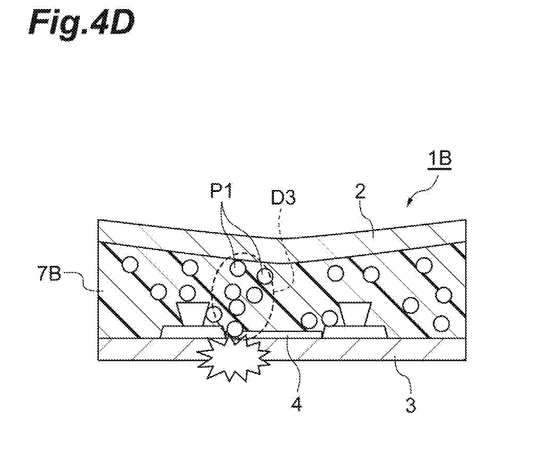

Next, an influence due to the powdered drying agent on the organic EL element portion will be described, with reference to FIG. 4A to FIG. 4D.

In an organic EL display device 1B illustrated in FIG. 4A to FIG. 4D, a filler 7B is disposed in the area overlapping the organic EL element portion 4 in the layer-stacked direction, between the first substrate 2 and the second substrate 3.

FIG. 4A illustrates a state where the influence due to the powdered drying agent P1 on the organic EL element portion 4 is not generated.

FIG. 4B illustrates a case where aggregation of the powdered drying agent P1 occurs in an area D1 within the filler 7B. In this case, there is a high possibility that the powdered drying agent P1 is in contact with the organic EL element portion 4, and if the powdered drying agent P1 mechanically damages the organic EL element portion 4, the organic EL element is damaged, a dielectric breakdown occurs, and a rate of occurrence of a leak failure is increased.

FIG. 4C illustrates a case where uniformity of the concentration of the powdered drying agent P1 is not sufficient, and a portion of which the concentration is high locally occurs, in an area D2 within the filler 7B. In this case, there is a high possibility that the powdered drying agent P1 is in contact with the organic EL element portion 4, and if the powdered drying agent P1 mechanically damages the organic EL element portion 4, the organic EL element is damaged, the dielectric breakdown occurs, and the rate of occurrence of the leak failure is increased.

FIG. 4D illustrates a case where the first substrate 2 is locally deformed to approach the second substrate 3. In this case, the powdered drying agent P1 in the filler 7B is pressed toward the organic EL element portion 4 by the first substrate 2. Thereby, there is a high possibility that the powdered drying agent P1 is in contact with the organic EL element portion 4, and if the powdered drying agent P1 mechanically damages the organic EL element portion 4, the organic EL element is damaged, the dielectric breakdown occurs, and the rate of occurrence of the leak failure is increased.

In the organic EL display device 1 according to the present embodiment, the first filler 12 which is in contact with the sealing layer 6 is disposed on the inside of the sealing layer 6, in the direction intersecting with the layer-stacked direction, and the first filler 12 includes the powdered drying agent P1. In the organic EL display device 1, it is possible to use the powdered drying agent of which the water catching performance is high, and since the powdered drying agent P1 is disposed on the inside of the sealing layer 6, it is possible to suitably catch the moisture which is permeated from the outside. Therefore, there is a low possibility that the moisture reaches the organic EL element portion 4 which is disposed further on the inside than the first filler 12. As a result, the influence due to the moisture on the organic EL element portion 4 is prevented, deterioration of the organic EL element portion 4 is prevented, and the lowering in reliability of the organic EL element portion 4 is prevented. In the organic EL display device 1, since the influence due to the moisture is prevented, oxidation or peeling of the cathode are prevented, thereby, it is possible to restrain occurrence of a dark spot in the organic EL element portion 4, and it is possible to prevent reduction of a light-emitting area.

In the organic EL display device 1, the concentration C1 of the powdered drying agent P1 in the first filler 12 which is disposed on the outside in the direction intersecting with the layer-stacked direction, is higher than that in the second filler 13 which is disposed on the inside. In other words, the concentration C2 of the powdered drying agent P1 in the second filler 13 which is disposed on the inside is lower than the concentration C1 of the powdered drying agent P1 in the first filler 12 which is disposed on the outside. That is, in a comparison with a case where the concentration of the powdered drying agent P1 is uniform throughout the filler 7, in the organic EL display device 1, the amount of the powdered drying agent P1 which is disposed in the area not overlapping the organic EL element 4 is increased, thereby, it is possible to reduce the amount of the powdered drying agent P1 which is disposed in the area overlapping the organic EL element portion 4.

In this manner, the concentration C2 of the powdered drying agent P1 in the second filler 13 with which the area overlapping the organic EL element portion 4 in the layer-stacked direction is filled is made small, thereby, it is possible to prevent the occurrence of the aggregation of the powdered drying agent P1 or the local occurrence of the high concentration portion. Thereby, a concern that the powdered drying agent P1 strikes the organic EL element portion 4 is prevented, and a concern that the organic EL element portion 4 is damaged by the powdered drying agent P1 is reduced. Therefore, the occurrence of the dielectric breakdown, and the occurrence of the leakage in the organic EL element portion 4 are prevented. As a result, it is possible to realize the organic EL display device 1 that achieves the improvement in reliability of the organic EL element portion 4.

In the organic EL display device 1, the first filler 12 including the powdered drying agent P1 surrounds the organic EL element portion 4, thereby, is disposed around the whole circumference thereof. Thereby, before the moisture reaches the organic EL element portion 4, the water is reliably caught by the drying agent of the first filler 12. Therefore, the influence due to the moisture on the organic EL element portion 4 is prevented, the deterioration of the organic EL element portion 4 is prevented, and the lowering in reliability is further prevented.

In the organic EL display device 1, since it is possible to keep the concentration of the powdered drying agent P1 in the second filler 13 with which the area overlapping the organic EL element portion 4 in the layer-stacked direction is filled low, even in a case where the organic EL display device 1 is deformed, it is possible to reduce a concern that the powdered drying agent P1 strikes the organic EL element portion 4. Therefore, it is possible to realize the organic EL display device 1 which has suitable flexibility, and achieves the improvement in water catching performance and reliability.

In the organic EL display device 1, since it is possible to keep the concentration of the powdered drying agent P1 in the second filler 13 with which the area overlapping the organic EL element portion 4 in the layer-stacked direction is filled low, even if the distance between the first substrate 2 and the second substrate 3 in the layer-stacked direction is made small, it is possible to reduce a concern that the powdered drying agent P1 strikes the organic EL element portion 4. Therefore, it is possible to achieve the reduction in thickness of the organic EL display device 1, and it is possible to realize the organic EL display device that achieves the improvement in water catching performance and reliability.

### Example 1

Next, an organic EL display device 1 according to Example 1 will be described. The descriptions which are the same as those in the embodiments described above will be omitted.

In the organic EL display device 1 of Example 1, a sealing layer 6 was formed using a UV adhesive (manufactured by ThreeBond International, Inc.). In Example 1, a powdered inorganic oxide drying agent (calcium oxide, product name: OleDry-P3, manufactured by Futaba Corporation) was added to a curable resin (manufactured by Shin-Etsu Chemical Co., Ltd.), thereby, a concentration C1 of the inorganic oxide drying agent was set to be 30 wt % to 55 wt %, and a resultant material was used as a first filler 12. In Example 1, the first filler 12 was disposed around a whole circumference of an organic EL element portion 4 to surround the organic EL element portion 4. A water catching capacity of the first filler 12 was 32 wt % at a theoretical value.

In Example 1, a powdered inorganic oxide drying agent (calcium oxide) was added to a curable resin (manufactured by Shin-Etsu Chemical Co., Ltd.), thereby, a concentration C2 of the inorganic oxide drying agent was set to be 5 wt % to 20 wt %, and a resultant material was used as a second filler 13. The water catching capacity of the second filler 13 was 15 wt % at a theoretical value.

In Example 1, a width W1 of the sealing layer 6 was set to be 1.5 mm, and a width W2 of the first filler 12 was set to be 1.5 mm. Using a dispenser, the sealing layer 6, the first filler 12, and the second filler 13 were applied onto a first substrate 2. Under a pressure reduction environment, the first substrate 2 and a second substrate 3 were bonded to each other, and ultraviolet irradiation by a UV lamp and a heating treatment by a heater were performed, thereby, the UV adhesive was cured, and the sealing layer 6 was formed.

A case where an inside of the sealing layer 6 was filled with the powdered inorganic oxide drying agent was referred to as Comparative Example 1. A point at which Comparative Example 1 is different from Example 1 is a point that a filler which is the same as the first filler 12 is disposed in an area in which the second filler 13 is disposed. In Comparative Example 1, as a filler 7, a filler which was wholly the same as the first filler 12 was filled. The water catching capacity in Comparative Example 1 was 32 wt % at a theoretical value.

Next, regarding Example 1 and Comparative Example 1, an insulation failure test and a high temperature and high humidity acceleration life test of the organic EL element were performed. As an insulation failure test, regarding the organic EL element, it was determined whether or not a cathode and an anode were insulated, and a proportion of the organic EL elements which were not insulated among all the organic EL elements was referred to as a rate of occurrence of a leak failure. In Example 1, the rate of occurrence of the leak failure was 0%, whereas in Comparative Example 1, the rate of occurrence of the leak failure was 20%. In the insulation failure test, the test was carried out in an unused state as an initial inspection.

In the high temperature and high humidity acceleration life test, the organic EL display devices of Example 1 and Comparative Example 1 were respectively left at rest for 1400 hours under a condition that a temperature was set to be 60° C., and a humidity was set to be 95%. Here, the insulation failure test was carried out from a start of the test up to 1400 hours, and equal results were obtained in Example 1 and Comparative Example 1.

In the organic EL display device 1 according to Example 1, lowering in shrinkage life was not observed, in comparison with Comparative Example 1. In Example 1, the rate of occurrence of the leak failure was lowered, in comparison with Comparative Example 1.

### Example 2

Next, an organic EL display device 1 according to Example 2 will be described. The descriptions which are the same as those in the embodiments described above and Example 1 will be omitted.

A point at which Example 2 is different from Example 1 is a point that a second filler 13 including an organic metal (liquid state drying agent) is applied as a drying agent, in replacement of the second filler 13 including the powdered inorganic oxide drying agent as a drying agent. As an organic metal, aluminum alkoxide was used. The water catching capacity of the second filler 13 was 14 wt % at a theoretical value. The second filler 13 of Example 2 is a filler which does not include the powdered drying agent. The liquid state drying agent is a drying agent in a liquid state at the time of being manufactured (at the time of being applied) and at the time of being used.

Example 2 was manufactured in the same manner as that in Example 1, and regarding Example 2, the insulation failure test and the high temperature and high humidity acceleration life test of the organic EL element were performed. The test conditions were the same as those in Example 1 and Comparative Example 1 described above. In Example 2, the rate of occurrence of the leak failure was 0%. In the high temperature and high humidity acceleration life test, the test result of Example 2 was equal to the test results of Example 1 and Comparative Example 1.

In the organic EL display device 1 according to Example 2, the lowering in shrinkage life was not observed, in comparison with Comparative Example 1. In Example 2, the rate of occurrence of the leak failure was lowered, in comparison with Comparative Example 1.

The present disclosure is not limited to the embodiments and Examples described above, and can be variously modified as described below in the scope without departing from the gist of the present disclosure.

In the embodiments and Examples described above, the organic EL display device is not limited to the passive matrix type display device. For example, the organic El display device may be an active matrix type display device. In this case, a transistor or the like corresponding to each organic EL element is disposed.

In the embodiments and Examples described above, the organic EL display device may not be the see-through type display device. For example, at least one of the first substrate and the second filler may not have the light-transmitting property.

In the embodiments and Examples described above, both of the first substrate and the second substrate are not limited to the substantially rectangular shape when viewed from the layer-stacked direction. For example, both of the first substrate and the second substrate may have polygonal shapes or substantially circular shapes when viewed from the layer-stacked direction. In the same manner, the sealing layer which is disposed in the first substrate may have a polygonal frame shape or a substantially annular shape when viewed from the layer-stacked direction.

In the embodiments and Examples described above, the viscosities of the first filler 12 and the second filler 13 are not particularly limited, but may be a value that can flow, for example, at room temperature. The first filler 12 and the second filler 13 are not limited to be in the liquid state or in the gel state at the time of the filling, but may be, for example, in a sheet state.

In the embodiments and Examples described above, the filler 7 is configured to include two fillers (the first filler 12 and the second filler 13), but the filler 7 may be configured to include three or more fillers. For example, the first filler 12 may include the plurality of fillers. In the same manner, the second filler 13 may include the plurality of fillers. The “plurality of fillers” include a case where kinds of the drying agents are different from each other, and a case where the concentrations (wt %) of the drying agents are different from each other even when kinds of the drying agents are the same.

What is claimed is:

1. An organic EL display device comprising:
a first substrate that has a first main surface;
a frame-shaped sealing layer that is in contact with the first main surface, and is disposed along an edge of the first substrate;
a second substrate that is in contact with the sealing layer, and has a second main surface facing the first main surface;
an organic EL element portion that is disposed in a sealed space which is sealed by being surrounded with the first substrate, the sealing layer, and the second substrate on the second main surface; and
a filler with which the sealed space is filled,
wherein the filler has
a first filler that includes a powdered drying agent, and is in contact with the sealing layer on an inside of the sealing layer in a direction intersecting with a layer-stacked direction of the first substrate and the second substrate, and
a second filler that is in contact with the first filler on an inside of the first filler in the direction intersecting with the layer-stacked direction, and with which at least an area overlapping the organic EL element portion in the layer-stacked direction is filled.

2. The organic EL display device according to claim 1,
wherein a concentration of the powdered drying agent in the first filler is higher than a concentration of the powdered drying agent in the second filler.

3. The organic EL display device according to claim 1,
wherein the first filler is disposed in a frame shape surrounding the organic EL element portion, when viewed from the layer-stacked direction.

4. The organic EL display device according to claim 1,
wherein the first filler has a first drying agent as the drying agent, and
the second filler has a second drying agent of a kind which is different from the first drying agent.

5. The organic EL display device according to claim 1,
wherein the first filler has a curable resin, and an inorganic oxide drying agent as the drying agent, and
a concentration of the inorganic oxide drying agent in the first filler is 30 wt % or more and 55 wt % or less.

6. The organic EL display device according to claim 1,
wherein the second filler has a curable resin, and an inorganic oxide drying agent, and
a concentration of the inorganic oxide drying agent in the second filler is 5 wt % or more and 20 wt % or less.

7. The organic EL display device according to claim 1,
wherein the second filler includes an organic metal as a drying agent.

8. The organic EL display device according to claim 1,
wherein each of the first substrate, the second substrate, and the second filler has a light-transmitting property.

9. The organic EL display device according to claim 1,
wherein the first substrate and the second substrate are film-shaped substrates or glass substrates.

10. An organic EL display device comprising:
a first substrate and a second substrate;
an annular sealing layer interposed between the first substrate and the second substrate, a sealed space being formed with the first substrate, the sealing layer, and the second substrate;
an organic EL element portion disposed in the sealed space; and
a filler with which the sealed space is filled,
wherein the filler has
a first filler including a powdered drying agent at a first concentration, provided annularly so as to surround the organic EL element portion in the sealed space and to form a room with the first substrate, the organic EL element portion, and the second substrate and
a second filler including a powdered drying agent at a second concentration, provided so as to cover the organic EL element portion in the room,
wherein the second concentration is zero or greater but less than the first concentration.
